(19) United States
(12) Patent Application Publication
(10) Pub. No.: US 2025/0034698 A1
(43) Pub. Date: Jan. 30, 2025

(54) METHOD FOR DETECTING METAL MASK

(71) Applicant: DARWIN PRECISIONS CORPORATION, Hsinchu County (TW)

(72) Inventors: SEN LI CHEN, Hsinchu County (TW); KUANG YUN FAN, Hsinchu County (TW)

(21) Appl. No.: 18/646,807

(22) Filed: Apr. 26, 2024

(30) Foreign Application Priority Data
Jul. 26, 2023 (TW) 112127999

(51) Int. Cl. C23C 16/04; C23C 14/04; C23C 14/54; C23C 16/52

(52) U.S. Cl. CPC C23C 16/042; C23C 14/042; C23C 14/54; C23C 16/52

(57) ABSTRACT

A method for detecting a metal mask includes: providing a metal mask, where the metal mask has first sites arranged along a first long side, and a second site and a third site form a first straight line; calculating a vertical distance from each first site to the first straight line, where the vertical distance includes a first vertical distance; in a case that the first vertical distance is greater than 10 μm and not greater than 15 μm, determining a type of the metal mask, where the type includes a first type; in a case that the metal mask is of the first type, calculating a first distance between the second site and the third site, and a second distance between the fourth site and a central point of the first long side; and calculating the percentage of the second distance relative to the first distance.

### FIELD OF THE INVENTION

The present invention relates to a metal mask, and in particular to a precise metal mask for vapor deposition.

### BACKGROUND OF THE INVENTION

A metal mask is commonly used in the display industry. For example, in the manufacturing of a display panel, the metal mask is used to perform vapor deposition of a pixel material onto a substrate to form a pixel pattern, thereby requiring high precision. The metal mask is stretched and fixed at a supporting piece for vapor deposition operation. Stretching and fixing cause the metal mask to produce tension. Even if the metal mask is different in shape due to the influence of the manufacturing process and materials, the stretching result is unnecessarily affected, that is, within an allowable range, the change of the shape will not affect the stretching result. Only if the stretching result is abnormal, the vapor deposition quality will be affected. However, the stretching result cannot be predicted from the shape of the metal mask, and whether the result is normal or not can be known only after stretching, thereby causing a trial and error cost.

### SUMMARY OF THE INVENTION

The present invention provides a method for detecting a metal mask, which can be used to predict the stretching of the metal mask, thereby reducing the trial and error cost and improving the delivery quality.

The present invention further provides a method for stretching a metal mask, which can increase the stretching yield of the metal mask.

The present invention further provides a method for manufacturing a vapor deposition jig, which can increase the yield of the vapor deposition jig.

The method for detecting a metal mask provided by the present invention includes a step: providing a metal mask, where the metal mask has a plurality of sites, and a first long side and a second long side which are located on two opposite sides, the plurality of sites include a plurality of first sites arranged along the first long side, the plurality of first sites include a second site and a third site which are located at the head and the tail, and the second site and the third site form a first straight line; a step: calculating a vertical distance from each of the first sites other than the second site and the third site to the first straight line, where the plurality of first sites further include a fourth site, a vertical distance from the fourth site to the first straight line includes a first vertical distance, and the first vertical distance is greater than 10 μm or less than or equal to 10 μm; a step: in a case that the first vertical distance is greater than 10 μm and not greater than 15 μm, determining a type of the metal mask, where the type includes a first type; a step: in a case that the metal is of the first type, calculating a first distance and a second distance, where the first distance is a distance between the second site and the third site, and the second distance is a distance between the fourth site and a central point of the first long side; and a step: calculating the percentage of the second distance relative to the first distance, where the percentage is less than 15% or greater than or equal to 15%.

The method for stretching a metal mask provided by the present invention includes a step: providing a metal mask and evaluating the metal mask, including the steps in the above detection method; and a step: in a case that the first vertical distance is less than or equal to 10 μm, or the metal mask is of the first type and the percentage is less than 15%, stretching the metal mask.

The method for manufacturing a vapor deposition jig provided by the present invention includes a step: providing a metal mask and a frame body; a step: evaluating the metal mask, including the steps in the above detection method; and a step: in a case that the first vertical distance is less than or equal to 10 μm, or the metal mask is of the first type and the percentage of the second distance relative to the first distance is less than 15%, stretching the metal mask and fixing two opposite ends of the metal mask on a first frame wall and a second frame wall, respectively, where the two opposite ends are located in an extension direction of the first long side.

According to the method for detecting a metal mask provided by the present invention, the plurality of sites arranged along the first long side is adopted, and the first straight line, the first vertical distance, the first distance and the second distance are obtained from the plurality of sites, where the first vertical distance is less than or equal to 10 μm or greater than 10 μm, or greater than 10 μm or not greater than 15 μm, so that through different ranges of the first vertical distance, the determination of the type of the metal mask and the percentage of the second distance relative to the first distance, the stretching result can be predicted before the metal mask is stretched, and the trial and error cost can be reduced. According to the present invention, the stretching of the metal mask and the manufacturing of the vapor deposition jig adopt the above detection method, so the yield can be increased.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic flowchart of a method for detecting a metal mask according to an embodiment of the present invention;

FIG. 2 is a schematic top view of a metal mask according to a first embodiment of the present invention;

FIG. 3 is a schematic diagram of the layout of a metal mask design according to an embodiment of the present invention;

FIG. 4A is a schematic top view of a metal mask according to a second embodiment of the present invention;

FIG. 4B is a schematic diagram of the layout of a metal mask design according to a second embodiment of the present invention;

FIG. 5A is a schematic top view of a metal mask according to a third embodiment of the present invention;

FIG. 5B is a schematic diagram of the layout of a metal mask according to a third embodiment of the present invention;

FIG. 6A is a schematic top view of a metal mask according to a fourth embodiment of the present invention;

FIG. 6B is a schematic diagram of the layout of a metal mask according to a fourth embodiment of the present invention;

FIG. 7 is another schematic flowchart of a method for detecting a metal mask according to an embodiment of the present invention;

FIG. 8 is a schematic diagram of a vapor deposition jig design according to an embodiment of the present invention;

FIG. 9 is a schematic flowchart of a method for stretching a metal mask according to an embodiment of the present invention;

FIG. 10 is an operation schematic diagram of a method for stretching a metal mask according to an embodiment of the present invention; and

FIG. 11 is a schematic flowchart of a method for manufacturing a vapor deposition jig according to an embodiment of the present invention.

### DETAILED DESCRIPTION OF PREFERRED EMBODIMENTS

The foregoing and other technical contents and other features and advantages of the present invention will be clearly presented from the following detailed description of a preferred embodiment in cooperation with the accompanying drawings. Directional terms mentioned in the following examples, for example, upper, lower, left, right, front, back, top, or bottom, are only used to describe directions referring to the attached drawings. Therefore, the directional terms used are for illustration and not for limitation. In addition, terms such as “first” and “second” involved in the description or claims are merely used for naming the elements or distinguishing different embodiments or ranges rather than limiting the upper limit or lower limit of the quantity of the elements.

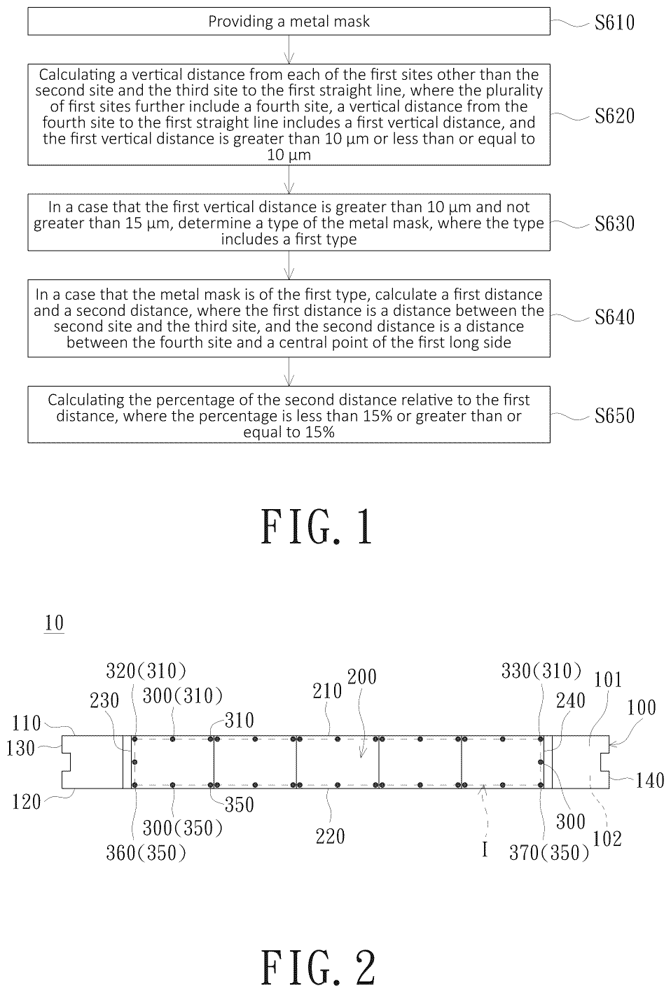

The present invention provides a method for detecting a metal mask, which can be used to determine whether the metal mask is suitable for a stretching process and can further be used for vapor deposition operation. As shown in FIG. 1, an embodiment of the detection method of the present invention includes steps S610-S650. Step S610 includes: providing a metal mask. The provided metal mask is described below according to the embodiment in FIG. 2.

FIG. 2 is a schematic top view of a metal mask according to an embodiment of the present invention. As shown in FIG. 2, the metal mask 10 may include a metal body 100 and a plurality of through holes (not shown in the figure). The metal body 100 is preferably plate-shaped and has a first surface 101 and a second surface 102 opposite to the first surface 101. The plurality of through holes pass through the metal body 100, are opened on the first surface 101 and the second surface 102, have a pattern design and can be applied to vapor deposition operation to achieve the pattern on a substrate. The metal mask 10 has a longer side and a shorter side in principle. The longer side may include a first long side 110 and a second long side 120 which are located on two opposite sides of the metal mask 10; and the shorter side may include a first short side 130 and a second short side 140 which are located on another two opposite sides of the metal mask 10. The metal mask 10 may further have a plurality of sites 300, and at least part of the sites 300 are arranged along the first long side 110. The sites 300 may have many purposes, for example, may be used for location and measurement, or may be used to define the shape of the metal mask 10. In a preferred embodiment of the present invention, the sites 300 may be holes and arranged along the first long side 110. The number and arrangement rule of the sites 300 in FIG. 2 are only examples, and the present invention is not limited thereto.

The sites 300 arranged along the first long side 110 are also referred to as first sites 310 herein. The first sites 310 further include a second site 320 and a third site 330 which are located at the head and the tail. That is, the number of the second site 320 and the third site 330 is one in principle, respectively. In addition, in a preferred embodiment of the present invention, a part of the sites 300 are arranged along the second long side 120. The sites 300 arranged along the second long side 120 are also referred to as the fifth sites 350 herein, where the fifth sites include a sixth site 360 and a seventh site 370 which are located at the head and the tail. The number of the sixth site 360 and the seventh site 370 is also one in principle, respectively. In the embodiments of the present invention, the second site 320 and the sixth site 360 may be close to a side of the first short side 130 of the metal mask 10, and the third site 330 and the seventh site 370 may be close to a side of the second short side 140. Preferably, a site 300 at a side of at least one first short side 130 is configured between the second site 320 and the sixth site 360. A site 300 at a side of at least one second short side is also configured between the third site 330 and the seventh site 370.

In several embodiments of the present invention, the first surface 101 of the metal body 100 further has a plurality of rectangular areas 200 which may be virtual or real areas. The plurality of rectangular areas 200 are preferably arranged along the extension direction of the first long side 110, and each of the rectangular areas 200 has two opposite sides 210 and 220 which are parallel to the first long side 110 and the second long side 120. Each of the rectangular areas 200 may include at least one working area (not shown in the figure), and the plurality of through holes are arranged at the working area. The working area may include a vapor deposition effective area. The plurality of sites 300 may be arranged in the rectangular areas 200 along the side 210 and the side 220. In several embodiments of the present invention, the sides 210 and 220 of each of the rectangular areas 200 are longer sides, and one or more sites 300, such as three sites, are arranged along the side 210 and the side 220, respectively; and sites 300 are arranged in two rectangular areas 200 at the head and the tail and along the short sides 230 and 240 on an outer side.

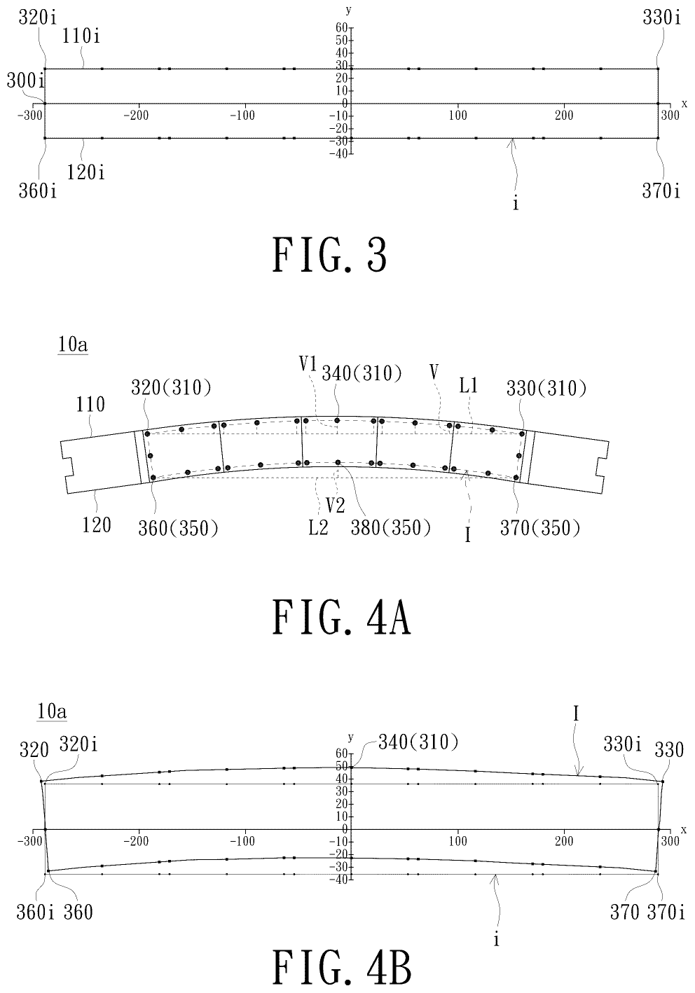

In the embodiments of the present invention, the plurality of sites 300 may be used to draw an XY scatter diagram, so that a closed loop graph can be obtained from the XY scatter diagram. The drawn closed loop graph may reflect the layout of each metal mask. FIG. 3 is a schematic diagram of a layout of metal mask design according to an embodiment of the present invention. FIG. 4A to FIG. 4B are a schematic top view and a schematic diagram of the layout of a metal mask according to another embodiment of the present invention. As shown in FIG. 3, the layout i of the metal mask design may be rectangular, where the first long side 110i and the second long side 120i are straight-line sides and correspond to the first long side 110 and the second long side 120 of the metal mask 10, respectively; a second site 320i and a third site 330i of sites 300i correspond to the second site 320 and the third site 330, respectively; and a sixth site 360i and a seventh site 370i correspond to the sixth site 360 and the seventh site 370, respectively. A straight line passing through the second site 320i and the third site 330i is parallel or overlapped with the first long side 110i, while a straight line passing through the sixth site 360i and the seventh site 370i is parallel or overlapped with the second long side 120i. However, in fact, due to the influence of the manufacturing process and materials, even if according to the design diagram, the manufactured metal mask, such as a metal mask 10a, may deviate from the design diagram, and the layout I drawn by the actual site 300 will have different types.

In the embodiments of the present invention, the plurality of sites 300 may be used for measurement. As shown in FIG. 1, step S620 includes: calculating a vertical distance from each of the first sites other than the second site and the third site to the first straight line, where the plurality of first sites further include a fourth site, a vertical distance from the fourth site to the first straight line includes a first vertical distance, and the first vertical distance is greater than 10 μm or less than or equal to 10 μm.

Taking the embodiment of FIG. 4A to FIG. 4B as an example, the first straight line in step S620 is a straight line L1 connecting the second site 320 with the third site 330. In the embodiment of FIG. 4A to FIG. 4B, the layout I of the metal mask 10a deviates from the design layout i shown by a dotted line, showing a type in which two ends are a lowest point or a highest point relative to the center. As shown in FIG. 4A, the first straight line L1 does not pass through the first sites 310 other than the second site 320 and the third site 330, and a vertical distance B between the plurality of first sites 310 other than the second site 320 and the third site 330 and the first straight line L1 tends to increase from two ends to the center. This type is also referred to as the first type.

The first sites 310 further include a fourth site 340, and a vertical distance V from the fourth site 340 to the first straight line L1 includes a first vertical distance V1. In a preferred embodiment of the present invention, the fourth site 340 is far away from the first straight line L1, and a value of the first vertical distance V1 is greater than other vertical distances V. In the first type, in general, the fourth site 340 is closer to the center of the first long side 110, and two ends of the metal mask 10a are the lowest point or the highest point more relative to the fourth site 340. In the embodiments of the present invention, the first vertical distance V1 has two cases: greater than 10 μm, and less than or equal to 10 μm.

In the embodiments of the present invention, each site 300 preferably has coordinates. The coordinates of the second site 320 and the coordinates of the third site 330 may form a straight-line equation, and the other first sites 310 can calculate the value of the vertical distance V through the coordinates and a vertical distance formula. In a case that (x₁, y₁) and (x₂, y₂) represent the Cartesian coordinates of the second site 320 and the third site 330, respectively, the formed straight-line equation may be shown in the following [Formula 1]:

$$y - {y}_{1} = \frac{{y}_{1} - {y}_{2}}{{x}_{1} - {x}_{2}} ( x - {x}_{1} ) . \qquad [ Formula 1 ]$$

In a case that (x₃, y₃) represents the Cartesian coordinates of the fourth site 340, the value of the first vertical distance V1 may be calculated by the following [Formula 2]:

$$d = \frac{\vert {ax}_{3} + {by}_{3} + c \vert}{\sqrt{{a}^{2} + {b}^{2}}} , \qquad [ Formula 2 ]$$

where a and b are coefficients of x and y in [Formula 1], respectively, and c is a constant.

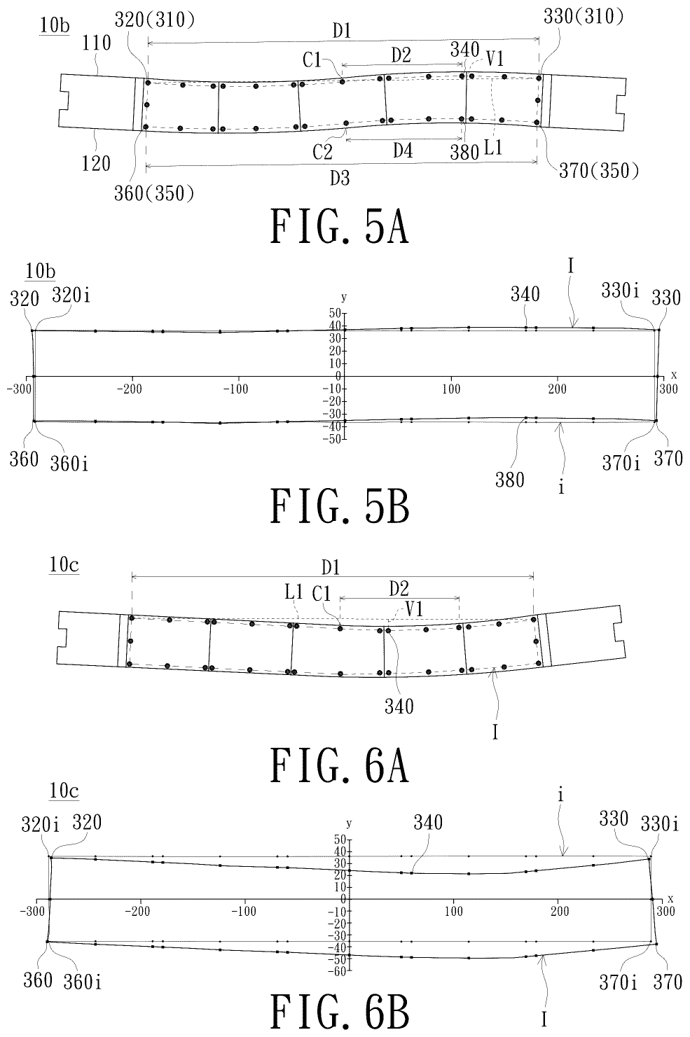

FIG. 5A to FIG. 5B are a schematic top view and a schematic diagram of the layout of a metal mask according to another embodiment of the present invention. Different from the metal mask 10a, the layout I of the metal mask 10b does not show a type in which two ends are the lowest point or the highest point relative to the center, referred to as a second type. In the second type, the first straight line L1 does not necessarily pass through the first sites 310 other than the second site 320 and the third site 330, and the vertical distance does not tend to increase from the two ends to the center. There may be a plurality of fourth sites 340, and the first vertical distance V1 also has two cases: greater than 10 μm, and less than or equal to 10 μm. In a preferred embodiment of the present invention, in a case that the first vertical distance V1 is less than or equal to 10 μm, the first type of metal mask 10a or the second type of metal mask 10b should be suitable for the stretching process and can be used for vapor deposition operation.

As shown in FIG. 1, step S630 includes: in a case that the first vertical distance is greater than 10 μm and not greater than 15 μm, determining a type of the metal mask, where the type includes a first type. Further, in a case that the first vertical distance is greater than 10 μm, an actual value of the metal mask deviates from a design value to a great extent. In the embodiments of the present invention, in a case that the metal mask is of the second type and the first vertical distance V1 is greater than 10 μm, it may be determined that the metal mask is not suitable for the stretching process. Otherwise, in a case that the metal mask is of the first type and the first vertical distance V1 is greater than 10 μm, determination is performed depending on whether V1 is greater than 15 μm. In a case that the first vertical distance is greater than 15 μm, it may be determined that the metal mask is not suitable for the stretching process; otherwise, in a case that the first vertical distance V1 is not greater than 15 μm, steps S640-S650 are performed.

As shown in FIG. 1, step S640 includes: in a case that the metal mask is of the first type, calculating a first distance and a second distance, where the first distance is a distance between the second site and the third site, and the second distance is a distance between the fourth site and a central point C1 of the first long side. The first distance is substantially parallel to the second distance. Step S650 includes: calculating the percentage of the second distance relative to the first distance, where the percentage is less than 15% or greater than or equal to 15%. Further, steps S640-S650 may detect the degree to which the highest (or lowest) site, such as the fourth site 340, of the first type of metal mask is close to the center. The embodiment of FIG. 4A to FIG. 4B is taken as an example. The metal mask 10a is of the first type. In a case that the first vertical distance V1 is greater than 10 μm and not greater than 15 μm and the percentage is less than 15% after calculation, it is determined that the metal mask is suitable for the stretching process and can be used for vapor deposition operation.

FIG. 6A to FIG. 6B are a schematic top view and a schematic diagram of the layout of a metal mask according to another embodiment of the present invention. The layout I of the metal mask 10c shows a type in which two ends are the lowest point relative to the center, which is thus the first type. Different from the metal mask 10a, the fourth site 340 of the metal mask 10c deviates from the center. In a case that the first vertical distance V1 of the metal mask 10c is greater than 10 μm and not greater than 15 μm and the percentage of a second distance D2 relative to a first distance D1 is greater than 15%, it may be determined that the metal mask is not suitable for the stretching process.

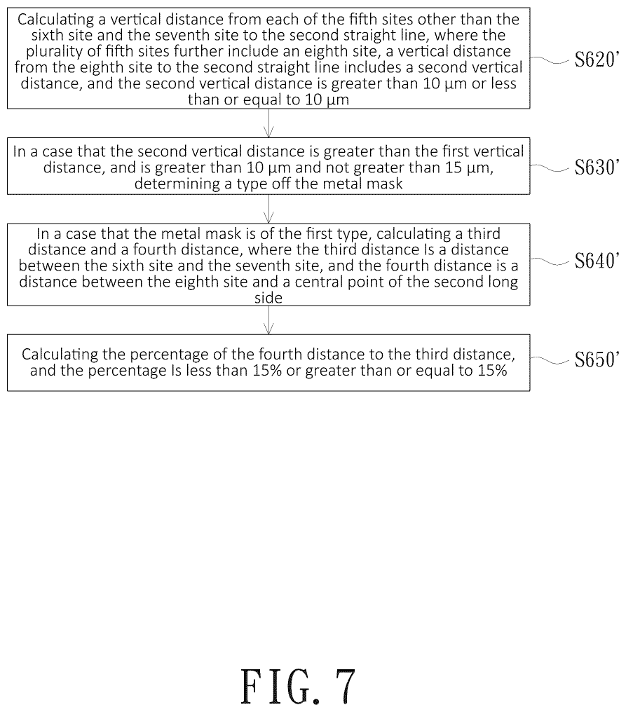

As shown in FIG. 7, the fifth site 350 may be used to perform steps S620′-S650′. As mentioned above, the fifth site 350 includes a sixth site 360 and a seventh site 370 which are located at the head and the tail. A straight line connecting the sixth site 360 with the seventh site 370 is a second straight line L2. The sixth site 360 further includes an eighth site 380. The distance between the eighth site 380 and the second straight line L2 is a second vertical distance V2. Referring to FIG. 5A, a third distance D3 is the distance between the sixth site 360 and the seventh site 370, and a fourth distance D4 is the distance between the eighth site 380 and the central point C2 of the second long side 120. In a preferred embodiment of the present invention, the eighth site 380 is far away from the second straight line L2, and a value of the second vertical distance V2 is greater than the vertical distance V from other fifth sites 350 to the second straight line L2.

The number and distribution of the sixth site 360 are preferably enough to reflect the layout I of the metal mask 10 and ensure the accuracy of steps S620′-S650′. For example, in a case that the metal mask 10 is of the first type, the eighth site 380 is preferably at a position where the second long side 120 between the sixth site 360 and the seventh site 370 is farthest away from the second straight line L2, and the second vertical distance V2 is a farthest distance between the second long side 120 and the second straight line L2. The same is true for the number and distribution of the first sites 310. In the embodiments of the present invention, the first sites 310 and the fifth sites 350 have the same number and are distributed symmetrically.

The following table illustrates the metal masks 10 with the serial numbers 1-26, the value of the first vertical distance V1 or the second vertical distance V2, and the percentage of the second distance D2 relative to the first distance D1 or the percentage of the fourth distance D4 relative to the third distance D3.

TABLE 1

| | | |
|---|---|---|
| | D2/D1 | Stretching |
| Serial | or D4/D3 | Results |

| | | | | |
|---|---|---|---|---|
| Number | V1 or V2 | (%) | Layout | (≤\|±3\|) |

| | | | | | |
|---|---|---|---|---|---|
| 1 | 8.06 | μm | 3% | First type | ∘ |
| 2 | 20.61 | μm | 5% | Second type | x |
| 3 | 9.38 | μm | 16% | First type | ∘ |
| 4 | 6.25 | μm | 17% | First type | ∘ |
| 5 | 16.86 | μm | 18% | Second type | x |
| 6 | 11.34 | μm | 10% | Second type | x |
| 7 | 14.66 | μm | 14% | First type | ∘ |
| 8 | 12.33 | μm | 11% | First type | ∘ |
| 9 | 11.35 | μm | 17% | First type | x |
| 10 | 6.62 | μm | 18% | Second type | ∘ |
| 11 | 3.68 | μm | 3% | Second type | ∘ |
| 12 | 7.82 | μm | 14% | First type | ∘ |
| 13 | 6.25 | μm | 21% | First type | ∘ |
| 14 | 14.32 | μm | 2% | First type | ∘ |
| 15 | 16.32 | μm | 4% | Second type | x |
| 16 | 10.52 | μm | 4% | First type | ∘ |
| 17 | 12.57 | μm | 13% | First type | ∘ |
| 18 | 11.99 | μm | 14% | First type | ∘ |
| 19 | 7.88 | μm | 4% | Second type | ∘ |
| 20 | 15.62 | μm | 10% | First type | x |
| 21 | 21.63 | μm | 5% | Second type | x |
| 22 | 17.33 | μm | 18% | First type | x |
| 23 | 8.36 | μm | 17% | Second type | ∘ |
| 24 | 14.33 | μm | 4% | Second type | x |
| 25 | 19.32 | μm | 24% | Second type | x |
| 26 | 14.75 | μm | 18% | Second type | x |

The embodiments of the present invention stretch the metal masks 10 with the serial numbers 1-26. Stretching may be performed in a known way. For example, the known method for manufacturing a vapor deposition jig may be referenced and the metal mask 10 is opened and fixed to a supporting piece, so that the metal mask 10 has a tension in an extension direction of the first lone side 110.

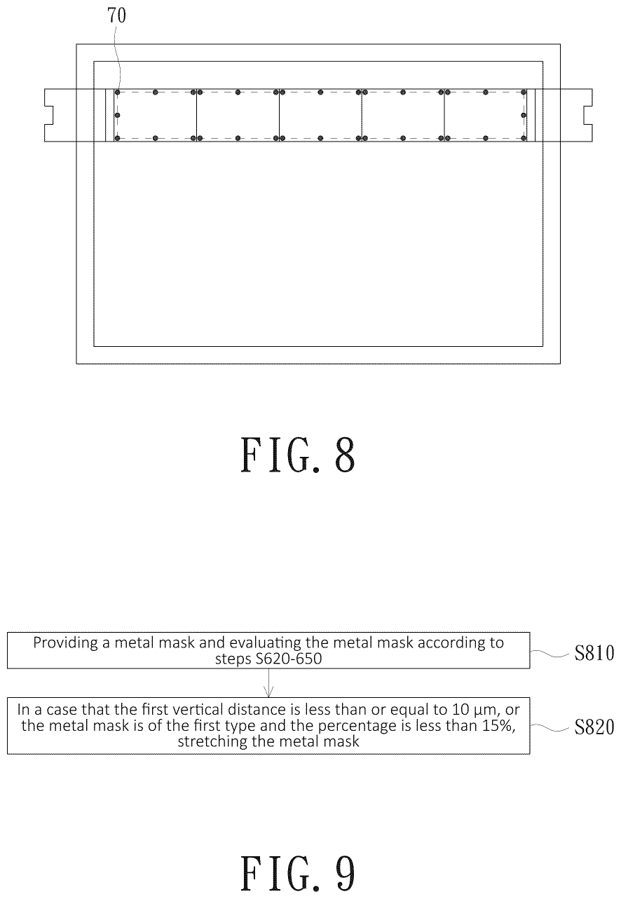

The embodiments of the present invention further compare the stretched metal mask 10 with the design diagram to understand the difference between the stretched metal mask 10 and the design value. The design diagram for comparison may be the design diagram of the above metal mask, or the design diagram of the vapor deposition jig, while the comparison method may be a comparison through a site 300. FIG. 8 is a schematic diagram of vapor deposition jig design according to an embodiment of the present invention; as shown in FIG. 8, there is a plurality of sites 70 in a design diagram 7. It may be understood that in the embodiments of the present invention, the vapor deposition jig includes a metal mask 10, and the metal mask 10 is fixed in the vapor deposition jig through stretching (described in detail later). All or some of the plurality of sites 300 of the metal mask 10 may have corresponding sites 70 in the design diagram 7. In several embodiments, the sites 300 at four corners of each rectangular area 200 of the metal mask 10 have corresponding sites 70 in the design diagram 7. For example, by comparing the Cartesian coordinates of 20 sites 300 on the metal mask 10 and the corresponding sites 70, 20 difference values may be obtained in an x direction and a y direction, respectively, that is, 40 difference values in total. In the embodiments of the present invention, as shown in Table 1, in a case that no difference value exceeds |±3|, the stretching results are normal, marked with ◯; otherwise, the stretching results are abnormal, marked with x. In several embodiments, 20 sites 300 on the metal mask 10 and the corresponding sites 300i thereof on the layout i may be compared, and 20 difference values may be obtained in an x direction and a y direction, respectively, that is, 40 difference values in total. There may be no difference between the sites 300i on the layout i and the sites 70 in the design diagram 7, and there is no difference between the part of the metal mask in the design diagram and the design diagram of the metal mask.

As shown in Table 1, the first vertical distance V1 or the second vertical distance V2 of the metal masks 10 with the serial numbers 1, 3-4, 10-13, 19 and 23 is less than or equal to 10 μm; and the layout I of these metal masks 10 includes a first type and a second type, and the stretching results are normal and conform to the specification. V1 or V2 of the metal masks 10 with the serial numbers 7-9, 14 and 16-18 is greater than 10 μm and not greater than 15 μm, and the layout is of the first type, where D2/D1 or D4/D3 of the serial numbers 7-8, 14 and 16-18 is less than 15%, and the stretching results are normal and conform to the specification; D2/D1 or D4/D3 of the serial number 9 is greater than 15%, and the stretching results do not conform to the specification. V1 or V2 of the metal masks 10 with the serial numbers 6, 24 and 26 is greater than 10 μm and not greater than 15 μm, the layout is of the second type, and the stretching results do not conform to the specification. V1 or V2 of the metal masks 10 with the serial numbers 2, 5, 15, 20-22 and 25 is greater than 10 μm and even greater than 15 μm, no matter the first or second type, the stretching results do not conform to the specification. Therefore, the detection method according to the embodiments of the present invention can determine whether the metal mask is suitable for the stretching process, and the stretching results may reach to an error≤|±3|.

The present invention further provides a method for stretching a metal mask. As shown in FIG. 9, the stretching method according to the embodiments of the present invention includes steps S810-S820. Step S810 includes: providing a metal mask and evaluating the metal mask; and the evaluation may be performed according to steps S620-S650. Step S820 includes: in a case that a first vertical distance is less than or equal to 10 μm, or the metal mask is of a first type and the percentage is less than 15%, stretching the metal mask. The evaluation in step S810 may be performed according to steps S620′-S650′.

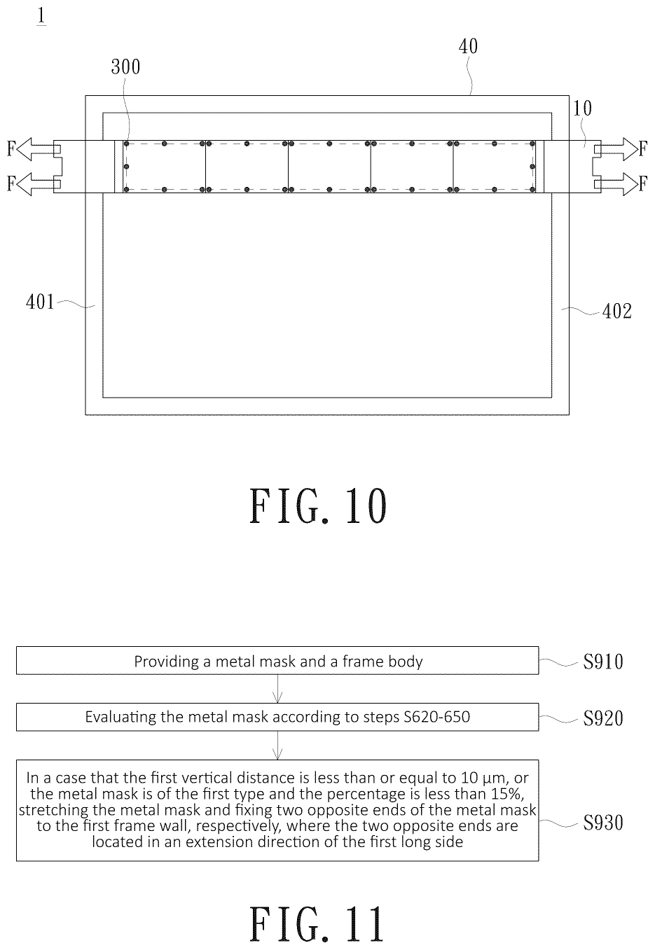

In a preferred embodiment of the present invention, step S820 further includes steps S821-S822. Step S821 includes: providing a frame body, where the frame body includes a first frame wall and a second frame wall which are located on two opposite sides. Step S822 includes: connecting the metal mask to the frame body, where two opposite ends of the metal mask are fixed to the first frame wall and the second frame wall, respectively, and have tensions, and the two opposite ends are located in an extension direction of a first long side. The operations in steps S821-S822 are shown in FIG. 10.

The present invention further provides a method for manufacturing a vapor deposition jig. As shown in FIG. 11, the method for manufacturing a vapor deposition jig according to the embodiments of the present invention includes steps S910-S930. Step S910 includes: providing a metal mask and a frame body. Step S920 includes: evaluating the metal mask. The evaluation may be performed according to steps S620-S650. Step S930 includes: in a case that a first vertical distance is less than or equal to 10 μm, or the metal mask is of a first type and the percentage is less than 15%, stretching the metal mask, and fixing the two opposite ends of the metal mask to a first frame wall and a second frame wall, respectively, where the two opposite ends are located in an extension direction of a first long side.

The metal mask 10 and the frame body 40 in step S910 may be referenced to the above, where taking Table 1 as an example, the provided metal mask 10 may include metal masks 10 with the serial numbers 1-26, and in step S920, the metal masks 10, for example, the metal masks 10 with the serial numbers 1, 3-4, 7-8, 10-14, 16-19 and 23, suitable for the stretching process are evaluated and selected. The evaluation in step S920 may be performed according to steps S620′-S650′, and the operation of step S930 may be referenced to FIG. 10. The stretched metal mask 10 in the vapor deposition jig 5 and the design diagram are further compared, and a distance between each site 300 and the corresponding site 70 is measured. In a preferred embodiment of the present invention, an x-direction difference value and a y-direction difference value between each site 300 and the corresponding site 70 are not greater than 3 μm.

In conclusion, the detection method according to the embodiments of the present invention can predict the stretching result of the metal mask, so the trial and error cost can be reduced. In a case that the detection method of the present invention is used for stretching the metal mask 10 and manufacturing the vapor deposition jig 5, ineffective stretching can be avoided, and the manufacturing yield of the vapor deposition jig can be ensured.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for detecting a metal mask, comprising:
providing a metal mask, wherein the metal mask has a plurality of sites, a first long side, and a second long side, the first long side and the second long side are respectively located on two opposite sides, the plurality of sites comprises a plurality of first sites arranged along the first long side, the plurality of first sites comprises a second site located at a head and a third site located at a tail, and the second site and the third site form a first straight line;
calculating a vertical distance from each of the first sites other than the second site and the third site to the first straight line, wherein the plurality of first sites further comprises a fourth site, a vertical distance from the fourth site to the first straight line comprises a first vertical distance, and the first vertical distance is greater than 10 μm or less than or equal to 10 μm;
in a case that the first vertical distance is greater than 10 μm and not greater than 15 μm, determining a type of the metal mask, wherein the type comprises a first type;
in a case that the metal mask is of the first type, calculating a first distance and a second distance, wherein the first distance is a distance between the second site and the third site, and the second distance is a distance between the fourth site and a central point of the first long side; and
calculating a percentage of the second distance to the first distance, and the percentage is less than 15% or greater than or equal to 15%.

2. The method for detecting the metal mask according to claim 1, wherein in a case that the metal mask is of the first type, two opposite ends of the first long side are a lowest point or a highest point relative to the fourth site.

3. The method for detecting the metal mask according to claim 1, wherein the plurality of sites further comprises a plurality of fifth sites arranged along the second long side, the plurality of fifth sites comprises a sixth site located at a head and a seventh site located at a tail, and the sixth site and the seventh site form a second straight line.

4. The method for detecting the metal mask according to claim 3, further comprising:
calculating a vertical distance from each of the fifth sites other than the sixth site and the seventh site to the second straight line, wherein the plurality of fifth sites further comprises an eighth site, a vertical distance from the eighth site to the second straight line comprises a second vertical distance, and the second vertical distance is greater than 10 μm or less than or equal to 10 μm;
in a case that the second vertical distance is greater than the first vertical distance and is greater than 10 μm and is not greater than 15 μm, determining the type of the metal mask;
in a case that the metal mask is of the first type, calculating a third distance and a fourth distance, wherein the third distance is a distance between the sixth site and the seventh site, and the fourth distance is a distance between the eighth site and a central point of the second long side; and
calculating a percentage of the fourth distance to the third distance, and the percentage is less than 15% or greater than or equal to 15%.

5. The method for detecting the metal mask according to claim 1, wherein the metal mask comprises a metal body, a surface of the metal body comprises a plurality of rectangular areas arranged along an extension direction of the first long side, each of the rectangular areas has two opposite sides parallel to the first long side and the second long side, and the plurality of first sites and the plurality of second sites are arranged along the two opposite sides, respectively.

6. The method for detecting the metal mask according to claim 1, wherein each of the plurality of sites has a coordinate, the coordinate of the second site is (x₁, y₁), the coordinate of the third site is (x₁, y₁), and the second site and the third site form a straight-line equation [Formula 1]:
$$y - {y}_{1} = \frac{{y}_{1} - {y}_{2}}{{x}_{1} - {x}_{2}} ( x - {x}_{1} ) .$$

7. The method for detecting the metal mask according to claim 6, wherein the coordinate of the fourth site is (x₃, y₃), and a value of the first vertical distance is calculated by the following formula [Formula 2]:
$$d = \frac{\vert {ax}_{3} + {by}_{3} + c \vert}{\sqrt{{a}^{2} + {b}^{2}}} ;$$
where a and b are coefficients of x and y in [Formula 1], respectively, and c is a constant.

8. A method for stretching a metal mask, comprising:
providing a metal mask and evaluating the metal mask, wherein the metal mask has a plurality of sites, a first long side, and a second long side, the first long side and the second long side are respectively located on two opposite sides, the plurality of sites comprises a plurality of first sites arranged along the first long side, the plurality of first sites comprises a second site located at a head and a third site located at a tail, the second site and the third site form a first straight line, and the evaluation comprises:
calculating a vertical distance from each of the first sites other than the second site and the third site to the first straight line, wherein the plurality of first sites further comprises a fourth site, a vertical distance from the fourth site to the first straight line comprises a first vertical distance, and the first vertical distance is greater than 10 μm or less than or equal to 10 μm;
in a case that the first vertical distance is greater than 10 μm and not greater than 15 μm, determining a type of the metal mask, wherein the type comprises a first type;
in a case that the metal mask is of the first type, calculating a first distance and a second distance, wherein the first distance is a distance between the second site and the third site, and the second distance is a distance between the fourth site and a central point of the first long side; and
calculating a percentage of the second distance to the first distance, and the percentage is less than 15% or greater than or equal to 15%; and
in a case that the first vertical distance is less than or equal to 10 μm, or the metal mask is of the first type and the percentage is less than 15%, stretching the metal mask.

9. The method for stretching the metal mask according to claim 8, wherein the plurality of sites further comprises a plurality of fifth sites arranged along the second long side, the plurality of fifth sites comprises a sixth site located at a head and a seventh site located at a tail, and the sixth site and the seventh site form a second straight line.

10. The method for stretching the metal mask according to claim 9, wherein the evaluation further comprises:
calculating a vertical distance from each of the fifth sites other than the sixth site and the seventh site to the second straight line, wherein the plurality of fifth sites further comprises a first eighth site, a vertical distance from the eighth site to the second straight line comprises a second vertical distance, and the second vertical distance is greater than 10 μm or less than or equal to 10 μm;
in a case that the second vertical distance is greater than the first vertical distance and is greater than 10 μm and is not greater than 15 μm, determining a type of the metal mask;
in a case that the metal mask is of the first type, calculating a third distance and a fourth distance, wherein the third distance is a distance between the sixth site and the seventh site, and the fourth distance is a distance between the eighth site and a central point of the second long side; and
calculating a percentage of the fourth distance relative to the third distance, and the percentage is less than 15% or greater than or equal to 15%.

11. The method for stretching the metal mask according to claim 10, further comprising:
in a case that the second vertical distance is less than or equal to 10 μm, or the metal mask is of the first type and the percentage of the fourth distance relative to the third distance is less than 15%, stretching the metal mask.

12. The method for stretching the metal mask according to claim 8, further comprising:
providing a frame body, wherein the frame body comprises a first frame wall and a second frame wall respectively located on two opposite sides; and
connecting the metal mask with the frame body, wherein two opposite ends of the metal mask are fixed to the first frame wall and the second frame wall respectively and have tensions, and the two opposite ends are located in an extension direction of the first long side.

13. A method for manufacturing a vapor deposition jig, comprising:
providing a metal mask and a frame body, wherein the metal mask has a plurality of sites, a first long side, and a second long side, the first long side and the second long side are respectively located on two opposite sides, the plurality of sites comprises a plurality of first sites arranged along the first long side, the plurality of first sites comprises a second site located at a head and a third site located at a tail, the second site and the third site form a first straight line, and the frame body comprises a first frame wall and a second frame wall respectively located on two opposite sides; and
evaluating the metal mask, comprising:
calculating a vertical distance from each of the first sites other than the second site and the third site to the first straight line, wherein the plurality of first sites further comprises a fourth site, and a vertical distance from the fourth site to the first straight line comprises a first vertical distance, and the first vertical distance is greater than 10 μm or less than or equal to 10 μm;
in a case that the first vertical distance is greater than 10 μm and not greater than 15 μm, determining a type of the metal mask, wherein the type comprises a first type;
in a case that the metal mask is of the first type, calculating a first distance and a second distance, wherein the first distance is a distance between the second site and the third site, and the second distance is a distance between the fourth site and a central point of the first long side;
calculating a percentage of the second distance to the first distance, and the percentage is less than 15% or greater than or equal to 15%; and
in a case that the first vertical distance is less than or equal to 10 μm, or the metal mask is of the first type and the percentage is less than 15%, stretching the metal mask, and fixing two opposite ends of the metal mask on the first frame wall and the second frame wall, respectively, wherein the two opposite ends are located in an extension direction of the first long side.

14. The method for manufacturing the vapor deposition jig according to claim 13, wherein the plurality of sites further comprises a plurality of fifth sites arranged along the second long side, the plurality of fifth sites comprises a sixth site located at a head and a seventh site located at a tail, and the sixth site and the seventh site form a second straight line.

15. The method for manufacturing the vapor deposition jig according to claim 14, wherein the evaluation further comprises:
calculating a vertical distance from each of the fifth sites other than the sixth site and the seventh site to the second straight line, wherein the plurality of fifth sites further comprises an eighth site, a vertical distance from the eighth site to the second straight line comprises a second vertical distance, and the second vertical distance is greater than 10 μm or less than or equal to 10 μm;
in a case that the second vertical distance is greater than the first vertical distance, and is greater than 10 μm and not greater than 15 μm, determining a type of the metal mask;
in a case that the metal mask is of the first type, calculating a third distance and a fourth distance, wherein the third distance is a distance between the sixth site and the seventh site, and the fourth distance is a distance between the eighth site and a central point of the second long site; and
calculating a percentage of the fourth distance relative to the third distance, wherein the percentage is less than 15% or greater than or equal to 15%.

16. The method for manufacturing the vapor deposition jig according to claim 15, further comprising:
in a case that the second vertical distance is less than or equal to 10 μm, or the metal mask is of the first type and the percentage of the fourth distance relative to the third distance is less than 15%, stretching the metal mask, and fixing two opposite ends of the metal mask on the first frame wall and the second frame wall, respectively.

17. The method for manufacturing the vapor deposition jig according to claim 13, further comprising:
comparing the stretched metal mask and a design diagram of the vapor deposition jig, wherein the design diagram of the vapor deposition jig has a plurality of sites corresponding to the plurality of sites of the metal mask, respectively; and
obtaining a difference value between each of the sites and the corresponding site.

18. The method for manufacturing the vapor deposition jig according to claim 17, wherein the difference value is not greater than 3 μm.
